(19) United States
(12) Patent Application Publication
(10) Pub. No.: US 2017/0263571 A1
(43) Pub. Date: Sep. 14, 2017

(54) ELECTRONIC COMPONENT BUILT-IN SUBSTRATE AND METHOD FOR MANUFACTURING THE SAME

(71) Applicant: IBIDEN CO., LTD., Ogaki (JP)

(72) Inventors: Teruyuki ISHIHARA, Ogaki (JP); Hiroyuki BAN, Ogaki (JP); Kosuke IKEDA, Ogaki (JP); Haiying MEI, Ogaki (JP)

(73) Assignee: IBIDEN CO., LTD., Ogaki (JP)

(21) Appl. No.: 15/453,964

(22) Filed: Mar. 9, 2017

(30) Foreign Application Priority Data
Mar. 9, 2016 (JP) 2016-046053

(51) Int. Cl. H01L 23/552; H01L 21/768; H01L 23/053; H01L 23/48

(52) U.S. Cl. CPC H01L 23/552; H01L 23/481; H01L 21/76898; H01L 21/76895; H01L 23/053

(57) ABSTRACT

An electronic component built-in substrate includes an insulating substrate having a through hole and an inner wall surrounding the through hole, an electronic component accommodated in the through hole of the substrate, a sealing member filling the through hole such that the sealing member is covering the electronic component in the through hole of the substrate and exposing a terminal of the electronic component on a first side of the substrate, and a shield layer structure including a first metal film and a second metal film formed such that the first metal film is formed on the inner wall of the substrate and surrounding the through hole of the substrate and that the second metal film is formed on a second side of the substrate on the opposite side with respect to the first side and covering an opening of the through hole on the second side of the substrate.

### CROSS-REFERENCE TO RELATED APPLICATIONS

The present application is based upon and claims the benefit of priority to Japanese Patent Application No. 2016-046053, filed Mar. 9, 2016, the entire contents of which are incorporated herein by reference.

### BACKGROUND OF THE INVENTION

Field of the Invention

The present invention relates to an electronic component built-in substrate having a metal film surrounding an electronic component, and relates to a method for manufacturing the electronic component built-in substrate.

Description of Background Art

International Publication No. 2014/069658 describes a high frequency module having a transmission circuit that generates a high frequency signal. The entire contents of this publication are incorporated herein by reference.

### SUMMARY OF THE INVENTION

According to one aspect of the present invention, an electronic component built-in substrate includes an insulating substrate having a through hole and an inner wall surrounding the through hole, an electronic component accommodated in the through hole of the insulating substrate, a sealing member filling the through hole such that the sealing member is covering the electronic component in the through hole of the insulating substrate and exposing a terminal of the electronic component on a first side of the insulating substrate, and a shield layer structure including a first metal film and a second metal film formed such that the first metal film is formed on the inner wall of the insulating substrate and surrounding the through hole of the insulating substrate and that the second metal film is formed on a second side of the insulating substrate on the opposite side with respect to the first side and covering an opening of the through hole on the second side of the insulating substrate.

According to another aspect of the present invention, a method for manufacturing an electronic component built-in substrate includes forming an insulating substrate having a through hole and an inner wall surrounding the through hole, forming a first metal film on the inner wall of the insulating substrate, positioning a base member on a first side of the insulating substrate such that an opening of the through hole on the first side is closed by the base member, positioning an electronic component on the base member in the through hole directly or via a conductor, filling a resin material in the through hole such that the resin material forms a sealing member filling the through hole and covering the electronic component in the through hole of the insulating substrate, forming a second metal film on a second side of the insulating substrate on the opposite side with respect to the first side such that the second metal film covers an opening of the through hole on the second side and makes contact with the first metal film, and removing the base member from the insulating substrate such that the sealing member exposes a terminal of the electronic component on the first side of the insulating substrate. The first metal film and the second metal film form a shield layer structure.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of an example of an electronic component built-in substrate of an embodiment of the present invention;

FIG. 2A is a plan view of an example of the electronic component built-in substrate of FIG. 1;

FIG. 2B is a bottom view illustrating a surface on a second conductor layer side of the electronic component built-in substrate of FIG. 1;

FIG. 3 is an enlarged view illustrating another example of a second conductor layer of the electronic component built-in substrate of FIG. 1;

FIG. 4A illustrates an example of a method for manufacturing the electronic component built-in substrate of the embodiment of the present invention;

FIG. 4B illustrates an example of a method for manufacturing the electronic component built-in substrate of the embodiment of the present invention;

FIG. 4C illustrates an example of a method for manufacturing the electronic component built-in substrate of the embodiment of the present invention;

FIG. 4D illustrates an example of a method for manufacturing the electronic component built-in substrate of the embodiment of the present invention;

FIG. 4E illustrates an example of a method for manufacturing the electronic component built-in substrate of the embodiment of the present invention;

FIG. 4F illustrates an example of a method for manufacturing the electronic component built-in substrate of the embodiment of the present invention;

FIG. 4G illustrates an example of a method for manufacturing the electronic component built-in substrate of the embodiment of the present invention;

FIG. 4H illustrates an example of a method for manufacturing the electronic component built-in substrate of the embodiment of the present invention;

FIG. 4I illustrates an example of a method for manufacturing the electronic component built-in substrate of the embodiment of the present invention;

FIG. 4J illustrates an example of a method for manufacturing the electronic component built-in substrate of the embodiment of the present invention;

FIG. 4K illustrates an example of a method for manufacturing the electronic component built-in substrate of the embodiment of the present invention; and

FIG. 4L illustrates an example of a method for manufacturing the electronic component built-in substrate of the embodiment of the present invention.

### DETAILED DESCRIPTION OF THE EMBODIMENTS

The embodiments will now be described with reference to the accompanying drawings, wherein like reference numerals designate corresponding or identical elements throughout the various drawings.

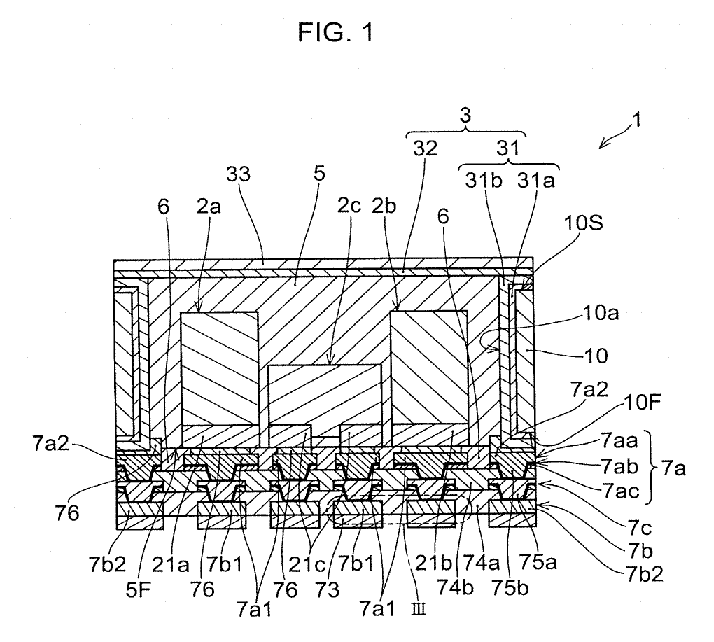

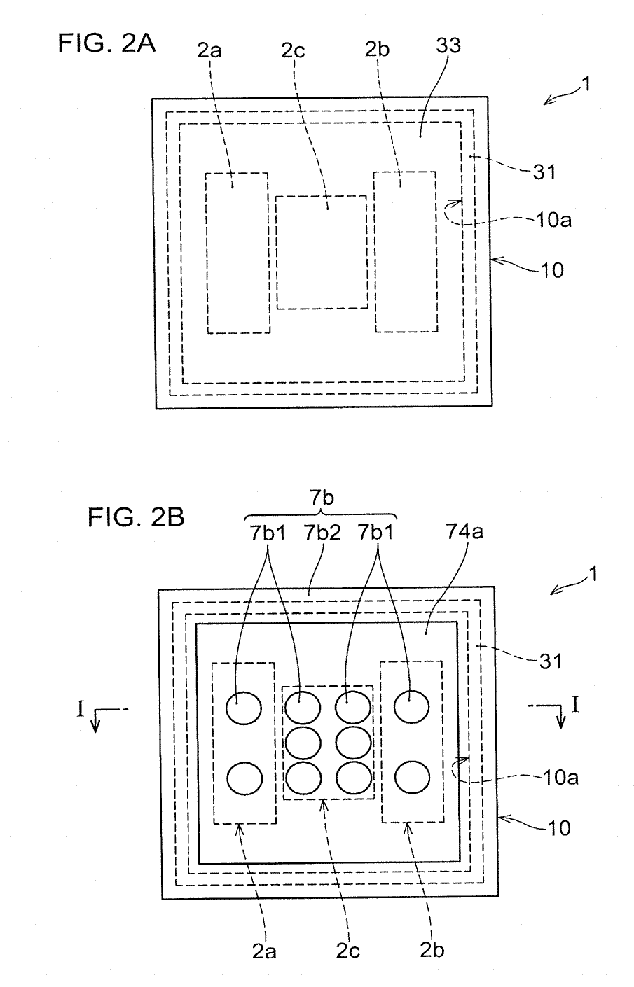

As illustrated in FIGS. 1, 2A and 2B, an electronic component built-in substrate 1 of the embodiment includes an insulating substrate 10 that has a through hole (10a), electronic components (2a-2c) that are accommodated in the through hole (10a), and a sealing member 5 that is filled in the through hole (10a) and covers the electronic components (2a-2c). Then, a first metal film 31 that includes a lower-layer film (31a) and an upper-layer film (31b) is formed on an inner wall surrounding the through hole (10a) of the insulating substrate 10. Further, as illustrated in FIG. 1, on one surface (10F) side of the insulating substrate 10, terminals (21a-21c) of the respective electronic components (2a-2c) are exposed from the sealing member 5. FIG. 1 is a cross-sectional view along a line I-I illustrated in FIG. 2B.

The electronic components (2a-2c) are positioned in a hollow portion due to the through hole (10a) in the insulating substrate 10. As a result, of a total thickness of the electronic component built-in substrate 1, a portion occupied by the insulating substrate 10 and the electronic components (2a-2c) is reduced. That is, as compared to a case where the electronic components (2a-2c) are mounted on a surface of the insulating substrate 10, the total thickness of the electronic component built-in substrate 1 is reduced.

Further, the first metal film 31 is formed on the inner wall of the insulating substrate 10 surrounding the through hole (10a). Therefore, at least, radio wave leakage from the electronic components (2a-2c) in the through hole (10a) to a lateral direction (direction orthogonal to a thickness direction of the insulating substrate 10) is suppressed. An electronic component built-in substrate 1 having good characteristics with little radio wave leakage to outside can be obtained. There is less adverse effect on an electrical circuit or the like around the electronic component built-in substrate 1. In particular, in the electronic component built-in substrate 1, as illustrated in FIG. 2A, the first metal film 31 is formed on the entire inner wall that surrounds the through hole (10a). The first metal film 31 surrounds the entire circumference of the peripheral edge of the through hole (10a). Radio wave leakage from the electronic components (2a-2c) is likely to be small in all lateral directions. However, it is also possible that the first metal film 31 is formed on only a portion of the inner wall. This is because, at least, radio wave leakage from the portion having the first metal film 31 is reduced.

Further, in the present embodiment, a second metal film 32 is formed on the other surface (10S) side on an opposite side of the one surface (10F) of the insulating substrate 10. The second metal film 32 is mainly formed on a surface of the sealing member 5 on the other surface (10S) side of the insulating substrate 10, and covers the entire surface of the sealing member 5. That is, an opening part of the through hole (10a) on the other surface (10S) side of the insulating substrate 10 is covered by the second metal film 32. Therefore, radio wave leakage from the electronic components (2a-2c) to the other surface (10S) side of the insulating substrate 10 is suppressed. In the example illustrated in FIGS. 1 and 2A, a covering layer 33 is formed on the second metal film 32. The covering layer 33 covers the second metal film 32.

Further, in the example illustrated in FIG. 1, the first metal film 31 is formed to extend to the other surface (10S) of the insulating substrate 10. The first metal film 31 on the other surface (10S) of the insulating substrate 10 surrounds the opening part of the through hole (10a). An outer peripheral portion of the second metal film 32 is laminated on the first metal film 31 on the other surface (10S) of the insulating substrate 10, and is directly connected to the first metal film 31. The electronic components (2a-2c) are surrounded by the first metal film 31 and the second metal film 32 except the one surface (10F) side of insulating substrate 10. By connecting the conductive first metal film 31 and second metal film 32, a shield layer 3 having an electrically integrated structure having a side surface and a ceiling surface is formed. That is, the electronic components (2a-2c) are shielded from the outside by the shield layer 3 except the one surface (10F) side of the insulating substrate 10. Emission of radio waves from the electronic components (2a-2c) to the outside of the electronic component built-in substrate 1 is more effectively suppressed. Electrical characteristics of an electronic device of the like using the electronic component built-in substrate 1 can be stabilized. It is also possible that the first metal film 31 is not extended to the other surface (10S) of the insulating substrate 10. For example, it is also possible that the first metal film 31 is formed to reach up to the other surface (10S). Even in this case, the first metal film 31 and the second metal film 32 can be in contact with each other.

On the other hand, as illustrated in FIG. 1, on the one surface (10F) side of the insulating substrate 10, the terminals (21a-21c) of the respective electronic components (2a-2c) are exposed from a surface (5F) of the sealing member 5. It is not necessary to provide wirings or the like in the through hole (10a) for electrically connecting to the electronic components (2a-2c). Electrical connection between an external electrical circuit on the one surface (10F) side of the insulating substrate 10 and the electronic components (2a-2c) can be easily performed. The electronic components (2a-2c) and the external electrical circuit can be connected with a short path. Characteristics of the electronic component built-in substrate 1 can be stabilized. Further, it is not necessary to provide an opening part or the like in the shield layer 3 for the connection between the electronic components (2a-2c) and the external electrical circuit. Emission of radio waves from such an opening part is prevented.

As illustrated in FIG. 1, in the present embodiment, the electronic component built-in substrate 1 has a solder resist layer 6 and a first conductor layer (7a) on the one surface (10F) side of the insulating substrate 10. In the example of FIG. 1, the first conductor layer (7a) has a three-layer structure that includes a metal foil (7aa), a seed metal film (lab) and an electrolytic plating film (7ac). The first conductor layer (7a) includes multiple first conductor pads (7a1). The first conductor layer (7a) includes a second conductor pad (7a2) in addition to the first conductor pads (7a1). The electronic components (2a-2c) are mounted on the first conductor pads (7a1). The terminals (21a-21c) of the electronic components are fixed to the first conductor pads (7a1) by conductive bonding members 76 and are electrically connected to the first conductor pads (7a1). The solder resist layer 6 covers around the first conductor pads (7a1) and the second conductor pad (7a2).

The electronic component built-in substrate 1 further includes resin insulating layers (74b, 74a) and conductor layers (7c, 7b) on the one surface (10F) of the insulating substrate 10 via the first conductor layer (7a) and the solder resist layer 6. In the example of FIG. 1, from a far side from the insulating substrate 10, the second conductor layer (7b), the first resin insulating layer (74a), the third conductor layer (7c) and the second resin insulating layer (74b) are laminated in this order, and the first conductor layer (7a) and the solder resist layer 6 are formed on the second resin insulating layer (74b). The second conductor layer (7b) is built-in in the first resin insulating layer (74a) with one surface exposed from a surface of the first resin insulating layer (74a) on an opposite side of the insulating substrate 10. Bumps 73 of solder or the like are formed on the surface of the second conductor layer (7b) exposed from the first resin insulating layer (74a). The second conductor layer (7b) includes multiple third conductor pads (7b1) and a fourth conductor pad (7b2). The third conductor layer (7c) has the same three-layer structure as the first conductor layer (7a). Via conductors (75a, 75b) are respectively formed in the first and second resin insulating layers (74a, 74b). Conductor layers on both sides of each of the resin insulating layers are connected to each other by the via conductors (75a, 75b). The third conductor pads (7b1) are respectively electrically connected to the electrodes (21a-21c) of the electronic components via the via conductors (75a, 75b) and the first conductor pads (7a1). The fourth conductor pad (7b2) is electrically connected to the first metal film 31 via the via conductors (75a, 75b) and the second conductor pad (7a2).

A surface layer part of the electronic component built-in substrate 1 on an opposite side of the other surface (10S) of the insulating substrate 10 is formed by the second conductor layer (7b) and the first resin insulating layer (74a). By forming wiring patterns (not illustrated in the drawings) in appropriate shapes in the first-third conductor layers (7a-7c), the electronic components (2a-2c) can be electrically connected to an external electrical circuit at any position on the second conductor layer (7b). Further, since the second conductor layer (7b) is built-in in the first resin insulating layer (74a), solder short circuiting between the multiple third conductor pads (7b1) and between the third conductor pads (7b1) and the fourth conductor pad (7b2) is less likely to occur. Mounting yield and reliability of an electronic device using the electronic component built-in substrate 1 are likely to be high. Since the electronic component built-in substrate 1 illustrated in FIG. 1 has three conductor layers, a complex electrical circuit can be formed in the electronic component built-in substrate 1. It is also possible that the electronic component built-in substrate of the embodiment includes more conductor layers and resin insulating layers between the first conductor layer (7a) and the second conductor layer (7b).

In the example illustrated in FIGS. 1 and 2B, the first metal film 31 is formed to extend to the one surface (10F) of the insulating substrate 10. The first metal film 31 on the one surface (10F) of the insulating substrate 10 surrounds an opening part of the through hole (10a). The second conductor pad (7a2) is formed in a frame shape on the one surface (10F) of the insulating substrate 10 so as to connect to the first metal film 31, and is connected to the first metal film 31 by a bonding member 76 (since the bumps 73 substantially overlap with the third and fourth conductor pads (7b1, 7b2), illustration of the bumps 73 in FIG. 2B is omitted. Further, in FIG. 2B, the second conductor pad (7a2) having substantially the same shape as the fourth conductor pad (7b2) is formed at a position overlapping with the fourth conductor pad (7b2)). Due to the first metal film 31 and the second conductor pad (7a2) that surround the through hole (10a), propagation of radio waves from the through hole (10a) along the one surface (10F) of the insulating substrate 10 is effectively suppressed. Further, by connecting the fourth conductor pad (7b2) to a ground pattern of a motherboard, the shield layer 3 can be at a ground potential. The potential of the shield layer 3 can be stabilized and an excellent shielding effect can be obtained. It is also possible that the first metal film 31 is not extended to the one surface (10F) of the insulating substrate 10. For example, it is also possible that the first metal film 31 is formed to reach up to the one surface (10F). Even in this case, the first metal film 31 and the second conductor pad (7a2) can be connected to each other.

Positional relationship between the insulating substrate 10 and the electronic components (2a-2c) in the thickness direction of the electronic component built-in substrate 1 can be adjusted by supply amounts of the bonding members 76, a size of the second conductor pad (7a2), and the like. For example, it is possible that the amounts of the bonding members 76 are adjusted such that a surface of a portion of the first metal film 31 on the one surface (10F) of the insulating substrate 10 (surface facing the first conductor layer (7a)) is substantially coplanar with surfaces of the terminals (21a-21c) of the electronic components exposed from the surface (5F) of the sealing member 5. Stress acting on the bonding members 76 via the electronic components (2a-2c) and the insulating substrate 10 due to thermal expansion or the like of the sealing member 5 is expected to be dispersed in a relatively unbiased manner to the bonding members 76 on the first conductor pads (7a1) and on the second conductor pad (7a2).

A planar shape of the insulating substrate 10 (a shape projected on a plane orthogonal to the thickness direction of the insulating substrate 10; hereinafter, the term “planar shape” is used with the meaning) is not limited to a substantially square shape illustrated in FIGS. 2A and 2B, but may be any shape such as a rectangular shape or a circular shape. Further, the thickness of the insulating substrate 10 occupies a majority of the thickness of the electronic component built-in substrate 1, and defines an approximate thickness of the electronic component built-in substrate 1. The thickness of the insulating substrate 10 is, for example, 0.5 mm or more and 1.6 mm or less. A thickness (height) of each of the electronic components (2a-2c) that can be completely accommodated in the through hole (10a is determined by the thickness of the insulating substrate 10. In other words, the thickness of the insulating substrate 10 can be appropriately selected depending on the thicknesses of the electronic components accommodated in the through hole (10a). The insulating substrate 10 provides appropriate rigidity to the electronic component built-in substrate 1 and provides a formation region of the through hole (10a) and a formation region of the first metal film 31. A material of the insulating substrate 10 is not particularly limited as long as the material has these functions. For example, the material of the insulating substrate 10 may be an epoxy resin and may contain inorganic particles such as silica particles. Further, the insulating substrate 10 may contain a reinforcing material such as a glass cloth. Preferably a prepreg is used as the material of the insulating substrate 10.

The through hole (10a) is formed in the insulating substrate 10, for example, by irradiating laser or the like. In the example illustrated in FIG. 2A, the through hole (10a) has a substantially square planar shape and is located substantially at a center portion of the insulating substrate 10. However, the shape and size of the through hole (10a) and the position of the through hole (10a) in the insulating substrate 10 are not limited to those of the example illustrated in FIG. 2A. For example, the shape and size of the through hole (10a) can be determined according to electronic components to be accommodated in the through hole (10a). Further, in FIG. 1, a wall surface surrounding the through hole (10a) is substantially parallel to the thickness direction of the insulating substrate 10. However, for example, it is also possible that the wall surface surrounding the through hole (10a) is inclined toward a center side of the through hole (10a), or is inclined toward an opposite direction, as it extends toward the one surface (10F) side of the insulating substrate 10. That is, it is possible that the through hole (10a) is increased or reduced in diameter as it extends toward the one surface (10F) or the other surface (10S) of the insulating substrate 10.

It is possible that multiple electronic components (2a-2c) are accommodated in the through hole (10a) as illustrated in the drawings, or only one electronic component is accommodated in the through hole (10a). The electronic components (2a-2c) positioned in the through hole (10a) may be passive components or active components. Further, it is also possible that both passive components and active components are accommodated in one through hole (10a). It is possible that a wiring length between the electronic components is reduced. Examples of the passive components include inductors of a surface mount type or other forms, capacitors, resistors, and the like. Examples of the active components include bare chips, WLPs, or integrated circuit devices of other forms, transistors, or diodes, and the like, and particularly semiconductor elements that operate at high frequencies. However, the passive components and the active components are not limited to these.

The first metal film 31 is formed on the inner wall of the insulating substrate 10, and extends to the one surface (10F) and the other surface (10S) of the insulating substrate 10. In the example illustrated in FIG. 1, the first metal film 31 has a two-layer structure that includes the lower-layer film (31a) and the upper-layer film (31b). The lower-layer film (31a) is, for example, an electroless copper plating film, and the upper-layer film (31b) is, for example, an electrolytic copper plating film. However, the first metal film 31 is not limited to the structure illustrated in FIG. 1, and may include only one metal film or include three or more metal films. Further, the first metal film 31 may be a film formed of another metallic material such as nickel, or may be a sputtering film, a vapor deposition film, or the like. Further, the first metal film 31 on the one surface (10F) and on the other surface (10S) of the insulating substrate 10 does not necessarily have to surround the entire periphery of the through hole (10a). A first metal film 31 of any pattern can be formed on the one surface (10F) and on the other surface (10S) of the insulating substrate 10. For example, it is also possible that the first metal film 31 is not formed on the one surface (10F) and on the other surface (10S) of the insulating substrate 10. The first metal film 31 has a thickness of 3 μm or more and 15 μm or less, preferably, 5 μm or more and 10 μm or less. A good radio wave blocking effect is obtained and a formation time of the first metal film 31 is short.

The second metal film 32 covers the opening part of the through hole (10a) on the other surface (10S) side of the insulating substrate 10. The second metal film 32 is, for example, an electroless copper plating film. However, it is also possible that the second metal film 32 is a metal film formed using another film formation method using a metallic material other than copper, such as nickel. As illustrated in FIG. 1, when the second metal film 32 covers the entire opening part of the through hole (10a) and is connected to the first metal film 31 over the entire circumference of the opening part of the through hole (10a), the effect of blocking radio waves from the through hole (10a) is improved. However, it is also possible that the second metal film 32 is formed only on a portion of the opening part of the through hole (10a). Further, it is also possible that the second metal film 32 is only partly connected to the first metal film 31 around the opening part of the through hole (10a). This is because when the second metal film 32 is formed on at least a portion of the opening part of the through hole (10a), emission of radio waves from the through hole (10a) is reduced. The second metal film 32 has a thickness of 0.05 μm or more and 1 μm or less, preferably, 0.1 μm or more and 0.5 μm or less. A radio wave blocking effect is obtained and a formation time of the second metal film 32 is short.

The sealing member 5 is formed in the through hole (10a) and protects the electronic components (2a-2c) against a mechanical stress or the like from the outside of the electronic component built-in substrate 1. The sealing member 5 can reduce a stress acting on the bonding members 76 due to a change in temperature. The sealing member 5, specifically, mainly covers the solder resist layer 6 and the electronic components (2a-2c). Further, the sealing member 5 can also cover exposed portions of the first conductor layer (7a) and the bonding members 76 that are not covered by the solder resist layer 6 and the electronic components (2a-2c). The sealing member 5 can be formed of any insulating resin composition. An example of the material of the sealing member 5 is an epoxy resin. The epoxy resin may contain an inorganic filler such as silica. A content rate of the inorganic filler, for example, is 60% by mass or more and 90% by mass or less, and preferably 70% by mass or more and 90% by mass or less.

The first conductor pads (7a1) are provided according to the terminals (21a-21c) of the electronic components. The second conductor pad (7a2) is provided according to a pattern of the first metal film 31 on the one surface (10F) of the insulating substrate 10 and can be formed in any shape and size. An example of a material for the metal foil (7aa), the seed metal film (7ab) and the electrolytic plating film (7ac) that form the first conductor layer (7a) is copper. The material for the conductor layer (7a) is not particularly limited as long as the material has good conductivity. A material for the second conductor layer (7b) is also not particularly limited. The second conductor layer (7b) is preferably formed from an electrolytic copper plating film. A material for the third conductor layer (7c) is also not particularly limited, and the same material as the first conductor layer (7a) can be used. A layer structure of each of the first and third conductor layers (7a, 7c) is not limited to the three-layer structure illustrated in FIG. 1, and may be a sing-layer structure or a multilayer structure of more than three layers or less than three layers.

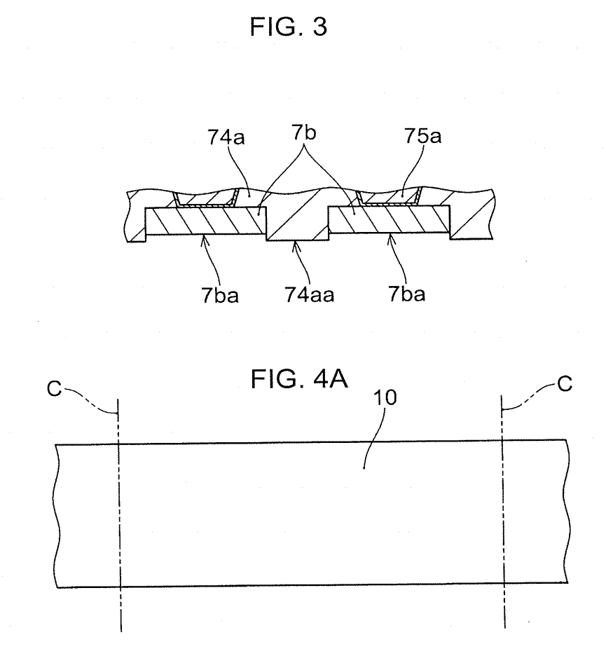

In the example of FIG. 1, the surface of the second conductor layer (7b) exposed from the first resin insulating layer (74a) is formed substantially coplanar with the surface of the first resin insulating layer (74a). However, as illustrated in FIG. 3, it is also possible that one surface (7ba) of the second conductor layer (7b) exposed from a surface (74aa) of the first resin insulating layer (74a) is recessed from the surface (74aa) of the first resin insulating layer (74a). FIG. 3 is an enlarged view of a portion corresponding to a III portion surrounded by a one-dotted chain line in FIG. 1 (illustrated of the bumps 73 illustrated in FIG. 1 is omitted). When the one surface (7ba) of the second conductor layer is recessed from the surface (74aa) of the first resin insulating layer, a contact failure between the bumps 73 (see FIG. 1) is unlikely to occur. A recess amount of the one surface (7ba) of the second conductor layer from the surface (74aa) of the first resin insulating layer is, for example, 0.1 μm or more and 5 μm or less. A reason why the one surface (7ba) of the second conductor layer can be recessed will be described later.

The solder resist layer 6 is formed at least between patterns of the first conductor layer (7a) in the through hole (10a). That is, the solder resist layer 6 is formed at least between the first conductor pads (7a1) and between the first conductor pads (7a1) and the second conductor pad (7a2). Contact between the bonding members 76 between the conductor pads can be prevented. It is also possible that, different from the example of FIGS. 1 and 2B, the solder resist layer 6 is also formed in a region surrounding the through hole (10a). For example, when the second conductor pad (7a2) is not formed over the entire circumference of the through hole (10a), the solder resist layer 6 can also be formed in a non-formation region of the second conductor pad (7a2).

The solder resist layer 6 has openings on the first and second conductor pads (7a1, 7a2). The bonding members 76 are supplied into the openings, and the electronic components (2a-2c) and the first conductor pads (7a1) are bonded to each other, and the insulating substrate 10 and the second conductor pad (7a2) are bonded to each other. The bonding members 76 are not particularly limited as long as the bonding members 76 have good conductivity and a strong bonding force. For example, solder or conductive adhesive can be used for the bonding members 76.

The covering layer 33 covers the entire surface of the second metal film 32. The second metal film 32 is protected by the covering layer 33 from an external environment to which the electronic component built-in substrate 1 is exposed during manufacturing or during use. For example, when the second metal film 32 is formed of copper, occurrence of rust or the like due to oxidation is prevented. Further, as will be described later, when the electronic component built-in substrate 1 is manufactured, the second metal film 32 is protected from an etching solution or the like. The covering layer 33, for example, may be a metal film such as a nickel film, which is different from the second metal film 32, or, for example, may be a resin film formed of an epoxy resin or the like. The material for the covering layer 33 is not limited to these.

In the example of FIG. 1, the multiple conductor layers including the first conductor layer (7a) are formed on the one surface (10F) side of the insulating substrate 10. However, it is also possible that only one conductor layer is formed on the one surface (10F) side of the insulating substrate 10.

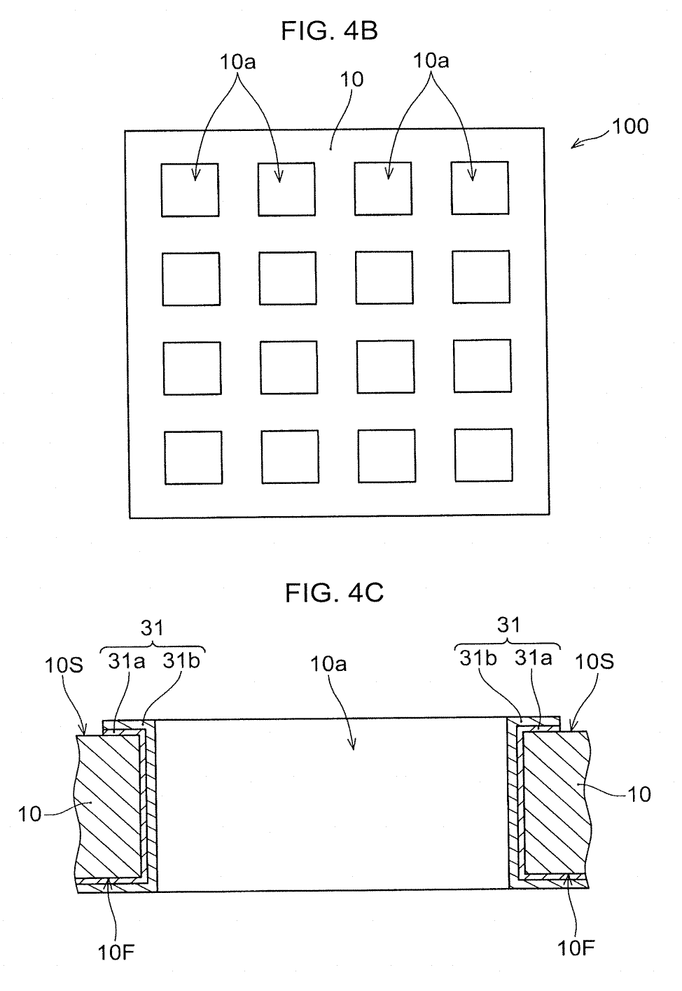

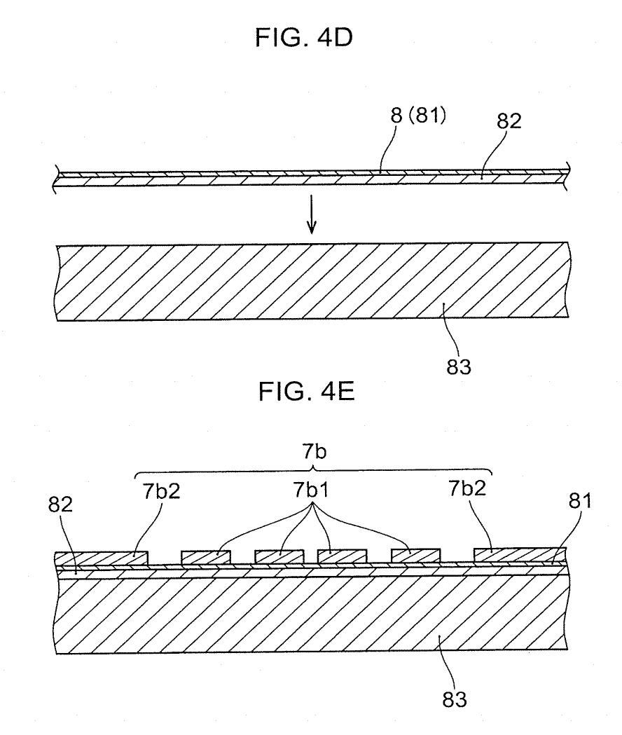

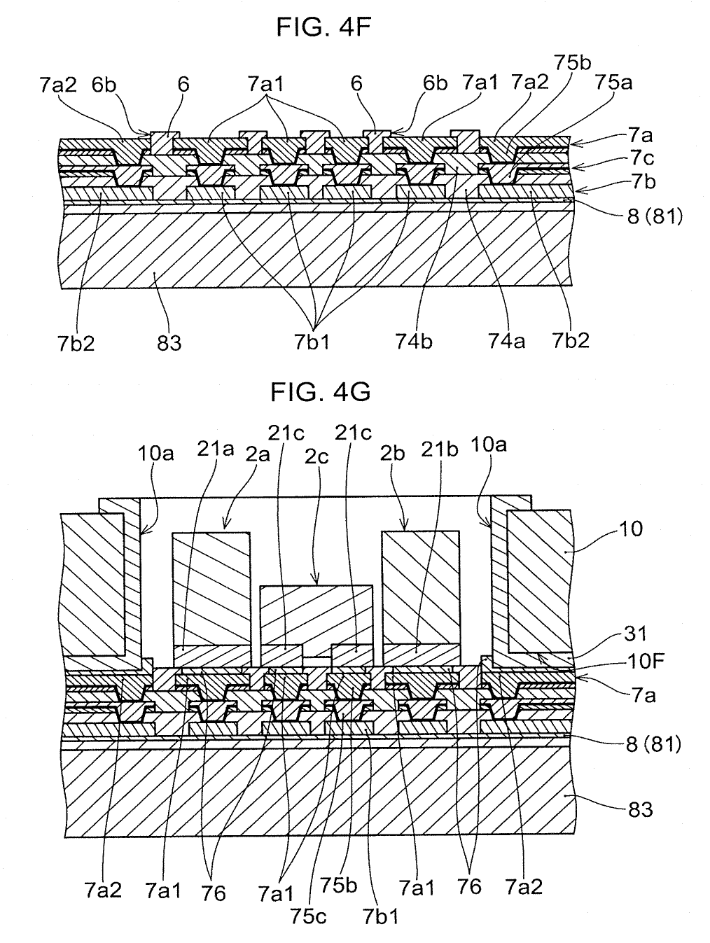

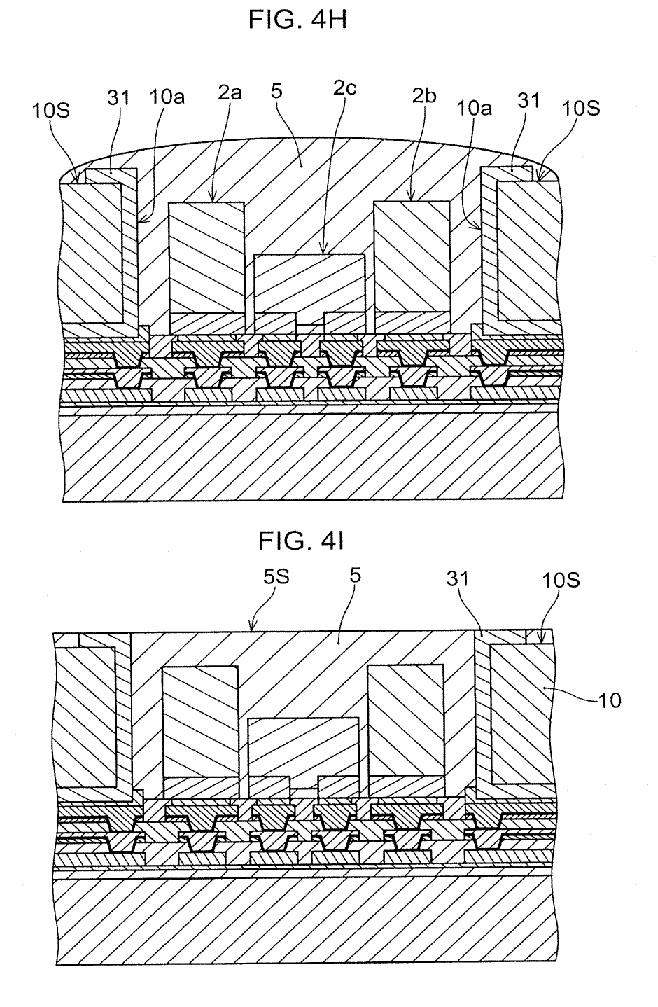

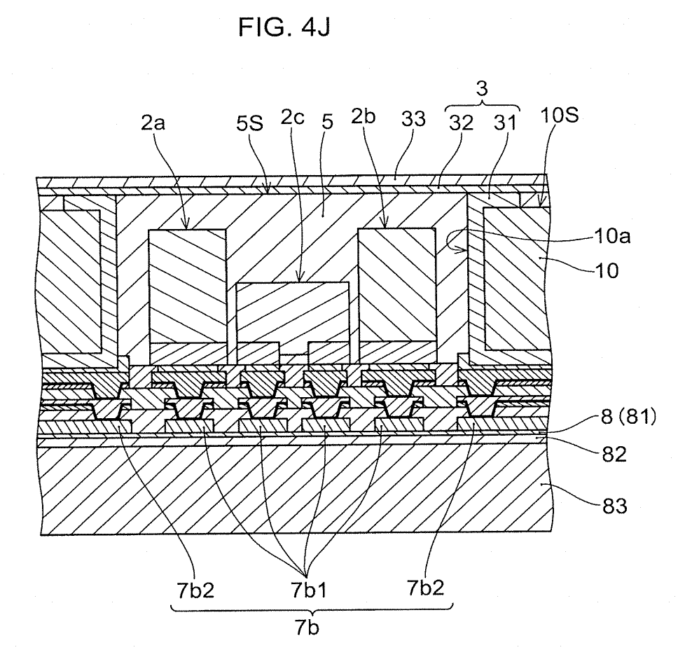

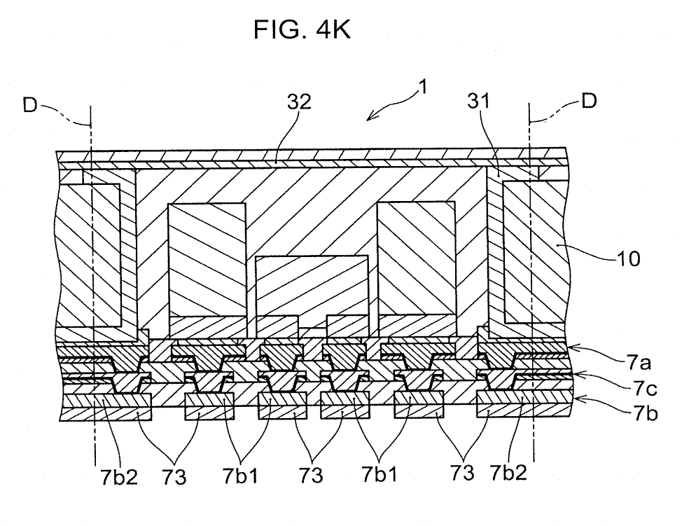

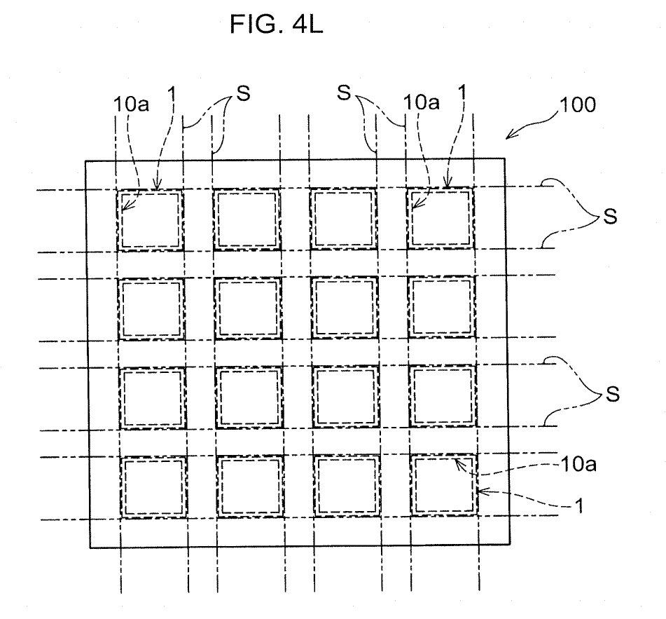

A method for manufacturing an electronic component built-in substrate of the embodiment is described with reference to FIG. 4A-4L using the electronic component built-in substrate 1 illustrated in FIG. 1 as an example.

As illustrated in FIG. 4A, the insulating substrate 10 is prepared. As described above, the insulating substrate 10 is not particularly limited in material as long as the insulating substrate 10 has appropriate rigidity or the like. For example, a glass epoxy plate obtained by fully curing a prepreg, or a double-sided copper-clad laminated plate obtained by laminating a copper foil on both sides of a prepreg, is prepared. FIG. 4A illustrates an example of an insulating substrate 10 that does not have a copper foil or the like.

A region between two two-dot chain lines (C) illustrated in FIG. 4A is removed and, as illustrated in FIG. 4B, the through hole (10a) is formed in the insulating substrate 10. FIG. 4B illustrates a large-sized insulating substrate 100 that is larger than the electronic component built-in substrate 1 (see FIG. 1). Multiple through holes (10a) are formed in the large-sized insulating substrate 100. When such a large-sized insulating substrate 100 is used, multiple electronic component built-in substrates 1 can be simultaneously manufactured. The electronic component built-in substrates 1 can be manufactured in a short period of time at low cost and in large quantities. However, it is also possible that the electronic component built-in substrate 1 is manufactured one by one from the formation of the through hole (10a) to completion. FIGS. 4A, 4C and 4G-4K each illustrate a cross section of a portion around one through hole (10a). The through hole (10a) can be formed using any appropriate processing method that does not excessively stress the insulating substrate 10, such as laser irradiation, cutting using a router, cutting using a drill, or punching using a die or the like.

As illustrated in FIG. 4C, the first metal film 31 is formed on the inner wall of the through hole (10a). In the example of FIG. 4C, the first metal film 31 is formed to also extend on the one surface (10F) and the other surface (10S) of the insulating substrate 10. The first metal film 31 is formed by forming the lower-layer film (31a) and the upper-layer film (31b). For example, the lower-layer film (31a) is formed by electroless plating, sputtering, vapor deposition, or the like, on the one surface (10F), the other surface (10S) and the entire surrounding inner wall of the through hole (10a) of the insulating substrate 10. Subsequently, the upper-layer film (31b) is formed on the entire surface of the lower-layer film (31a), for example, by electrolytic plating, and the first metal film 31 having the two-layer structure is formed. Preferably, copper is used for the lower-layer film (31a) and the upper-layer film (31b). Other metallic materials such as nickel may also be used.

When necessary, the first metal film 31 on the one surface (10F) and the other surface (10S) of the insulating substrate 10 is patterned using a tenting method or the like. In the example of FIG. 4C, a portion of the first metal film 31 on the other surface (10S) is removed. The first metal film 31 extends from the inside of the through hole (10a) over the entire circumference of the through hole (10a) to both the one surface (10F) and the other surface (10S) of the insulating substrate 10. The first metal film 31 is not necessarily required to be formed on the one surface (10F) and/or the other surface (10S) of the insulating substrate 10. Further, it is also possible that the upper-layer film (31b) is formed only in a required region using a pattern plating method.

Apart from the process illustrated in FIG. 4A-4C with respect to the insulating substrate 10, as illustrated in FIG. 4D-4F, a base member 8 is prepared.

As illustrated in FIG. 4D, as a base member 8, a metal foil 81 is prepared. Preferably, in order to obtain desired rigidity when the second conductor layer (7b) (see FIG. 4E) is formed in a subsequent process, as illustrated in FIG. 4D, the metal foil 81 bonded to a carrier metal foil 82 is prepared, and is bonded to a base substrate 83 on the carrier metal foil 82 side. The metal foil 81 and the carrier metal foil 82, for example, are bonded to each other with a separable adhesive such as a thermoplastic adhesive over an entire surface, or are bonded to each other only in a margin portion in a vicinity of an outer periphery. The metal foil 81 and the carrier metal foil 82 are preferably copper foils. Other metal foils such as a nickel foil may also be used. The carrier metal foil 82 and the base substrate 83, for example, are bonded to each other by thermal compression bonding. An adhesive or the like may also be used. A metal plate formed of copper or the like, or a prepreg, for example, is used for the base substrate 83. When a prepreg is used, the prepreg may be cured when being thermal compression bonded to the carrier metal foil 82.

As illustrated in FIG. 4E, the second conductor layer (7b) having the multiple third conductor pads (7b1) and the fourth conductor pad (7b2) at predetermined regions is formed on the metal foil 81. The second conductor layer (7b), for example, is formed by electrolytic copper plating using a plating resist having openings at formation regions of the third and fourth conductor pads (7b1, 7b2). The metal foil 81 can be used as a seed layer. Since etching is not used, the third and fourth conductor pads (7b1, 7b2) can be formed at a fine pitch. The second conductor layer (7b) may be formed to include any conductor pattern other than the third and fourth conductor pads (7b1, 7b2).

As illustrated in FIG. 4F, the first resin insulating layer (74a), the third conductor layer (7c), the second resin insulating layer (74b) and the first conductor layer (7a) are formed on the second conductor layer (7b). The first conductor layer (7a) is formed to include the multiple first conductor pads (7a1) and the second conductor pad (7a2). Further, the via conductors (75a, 75b) that connect between the first conductor pads (7a1) and the third conductor pads (7b1) and connect between the second conductor pad (7a2) and the fourth conductor pad (7b2) are formed. The first resin insulating layer (74a), the third conductor layer (7c), the second resin insulating layer (74b), the first conductor layer (7a) and the via conductors (75a, 75b), for example, can be formed, for example, using the same methods as those for manufacturing a build-up wiring board. For example, the first resin insulating layer (74a) is formed by thermal compression bonding a film-like epoxy resin or the like together with a metal foil on the second conductor layer (7b) and on an exposed portion of the metal foil 81. Via holes are formed in the first resin insulating layer (74a) by laser irradiation or the like. The third conductor layer (7c) and the via conductors (75a) are formed by forming a seed metal film by electroless plating or sputtering or the like and by forming an electrolytic plating film by pattern plating. The seed metal film and an unwanted portion of the metal foil below the seed metal film are removed by etching or the like. Then, the second resin insulating layer (74b), the first conductor layer (7a) and the via conductors (75b) are respectively formed using the same methods for forming the first resin insulating layer (74a), the third conductor layer (7c) and the via conductors (75a). A predetermined conductor pattern including the first conductor pads (7a1) and the second conductor pad (7a2) is formed in the first conductor layer (7a). It is also possible that the first and third conductor layers (7a, 7c) are formed by panel plating and patterning using a tenting method.

The solder resist layer 6 having openings (6b) on the first conductor pads (7a1) and the second conductor pad (7a2) is formed on the first conductor layer (7a) and on a surface of the second resin insulating layer (74b) exposed from the first conductor layer (7a). For example, a layer of a photosensitive epoxy resin material is forming on the first conductor layer (7a) and on the exposed portion of the second resin insulating layer (74b) by printing, spray coating or the like, and the openings (6b) are formed using a photolithography technology. As illustrated in FIG. 4F, the base member 8 is prepared from the metal foil 81 having the first conductor layer (7a) and the solder resist layer 6 on a surface on an opposite side of the base substrate 83.

In the example of FIG. 4D-4F, the metal foil 81 is laminated on only one side of the base substrate 83 via the carrier metal foil 82. However, it is also possible that a metal foil 81 is further laminated on the other side of the base substrate 83. In this case, subsequent processes can be performed on both sides of the base member 8. In FIG. 4G-4L and the following description, illustration and description for the other side of the base member 8 are omitted. However, the processes illustrated in FIG. 4G-4L may also be performed for the other side of the member 8 at substantially the same times as for the one side of the base member 8.

As illustrated in FIG. 4G, the insulating substrate 10 and the base member 8 are superimposed, and the electronic components (2a-2c) are positioned in the through hole (10a). In the example of FIG. 4G, the insulating substrate 10 is laminated on the base member 8 via the first conductor layer (7a) and the like with the one surface (10F) facing the base member 8 side. The opening part of the through hole (10a) on the one surface (10F) side of the insulating substrate 10 is closed by the base member 8 via the first conductor layer (7a) and the like. The electronic components (2a-2c) are positioned on the metal foil 81, that is, on the base member 8 via the conductors (in the example of FIG. 4G, the first and third conductor pads (7a1, 7b1) and the via conductors (75a, 75b)). The terminals (21a-21c) of the electronic components (2a-2c) are electrically connected to the first conductor pads (7a1) via the bonding members 76. The first metal film 31 on the one surface (10F) of the insulating substrate 10 is electrically connected to the second conductor pad (7a2) via the bonding members 76. In FIG. 4G, the first metal film 31 is simplified as one layer (the first metal film 31 is simplified also in FIG. 4H-4K). The base member 8 is provided with the base substrate 83 and thus is unlikely to deflect. Therefore, connection surfaces of the first conductor pads (7a1) and the second conductor pad (7a2) are substantially flat. The electronic components (2a-2c) and the insulating substrate 10 can be stably connected. An example of a material for the bonding members 76 is solder. However, the material for the bonding members 76 is not limited to solder, For example, a conductive adhesive containing conductive particles and a resin material can also be used for the bonding members 76.

When solder is used for the bonding members 76, the electronic components (2a-2c) and the insulating substrate 10 are preferably simultaneously soldered to the first conductor layer (7a) by solder reflow. In addition to that the bonding members 76 can be supplied on the first conductor layer (7a) at once, solder re-melting, which can occur when separately performing solder reflow, can be avoided. A highly reliable electronic component built-in substrate 1 can be efficiently manufactured. When another bonding material such as a conductive adhesive is used for the bonding members 76, the electronic components (2a-2c) and the insulating substrate 10 can also be simultaneously connected to the first conductor layer (7a). For example, it is also possible that the bonding members 76 are simultaneously supplied to the first and second conductor pads (7a1, 7a2), and the bonding members 76 are cured by heating after the electronic components (2a-2c) and the insulating substrate 10 are positioned, and thus the electronic components (2a-2c) and the insulating substrate 10 are simultaneously connected. However, it is also possible that the electronic components (2a-2c) and the insulating substrate 10 are separately connected to the first conductor layer (7a). Further, it is also possible that bonding materials of different kinds are respectively used as bonding members 76 for the electronic components (2a-2c) and the insulating substrate 10. For example, it is possible that solder is used for connecting the electronic components (2a-2c) and a conductive adhesive is used for connecting the insulating substrate 10. Then, it is possible that, first, the insulating substrate 10 and the second conductor pad (7a2) are connected to each other by a bonding member 76 formed of a conductive adhesive, and thereafter, a solder paste or the like is supplied onto the first conductor pads (7a1) using a dispenser or the like, and the electronic components (2a-2c) are mounted by solder reflow.

As illustrated in FIG. 4H, the through hole (10a) is filled with a resin material, and the sealing member 5 covering around the electronic components (2a-2c) is formed. For example, an epoxy resin containing an appropriate amount of an inorganic filler or the like is applied or injected into above and/or inside the through hole (10a) by mask printing or discharging from a nozzle, or the like. Alternatively, it is also possible that a resin material molded into a film-like shape is laminated on the other surface (10S) of the insulating substrate 10 so as to cover the through hole (10a). In either method, primary heating may be performed at a softening temperature of the resin material so that the through hole (10a) is thoroughly filled with the resin material. Further, it is also possible that the resin material is filled in a vacuum or decompressed atmosphere so as not to generate voids or the like. The sealing member 5 can be formed by heating the resin material filled in the through hole (10a) at a predetermined curing temperature to fully cure the resin material.

Preferably, the sealing member 5 is formed to completely fill the through hole (10a). This is because the electronic components (2a-2c) are sufficiently protected from an external stress and the formation of the second metal film 32 (see FIG. 4J) in a subsequent process becomes easy. Therefore, as illustrated in FIG. 4H, it is preferable that the sealing member 5 be formed so as to further protrude from the other surface (10S) of the insulating substrate 10 or from the surface of the first metal film 31 on the other surface (10S). This is because the through hole (10a) can be reliably filled without requiring fine control of a supply amount of the resin material.

When the sealing member 5 is formed so as to protrude from the other surface (10S) of the insulating substrate 10, after the formation of the sealing member 5, as illustrated in FIG. 4I, the protruding portion of the sealing member 5 is polished. The sealing member 5 is polished by polishing with a belt sander, buffing, chemical mechanical polishing, or the like. The sealing member 5 is polished such that a surface (5S) of the sealing member 5 on the other surface (10S) side of the insulating substrate 10 is substantially coplanar with the surface of the first metal film 31 on the other surface (10S) of the insulating substrate 10. When the first metal film 31 is not formed to reach the other surface (10S) of the insulating substrate 10, the sealing member 5 is polished such that the other surface (10S) of the insulating substrate 10 and the surface (5S) are substantially coplanar with each other. The surface of the first metal film 31 on the other surface (10S) of the insulating substrate 10 is a contact surface with the second metal film 32 (see FIG. 4J) that is formed in a subsequent process. When the first metal film 31 is not formed on the other surface (10S) of the insulating substrate 10, an end face of the first metal film 31 on the other surface (10S) side is “the surface of the first metal film 31 on the other surface (10S)”. Due to the polishing of the sealing member 5, the second metal film 32 that has a uniform thickness and allows a stable shielding effect to be achieved is formed.

As illustrated in FIG. 4J, the second metal film 32 is formed on the surface (5S) of the sealing member 5. The second metal film 32 is formed, for example, by electroless plating. It is also possible that the second metal film 32 is formed by sputtering or vapor deposition. In addition to the electroless plating or the like, electrolytic plating may also be performed. The second metal film 32 covers the opening part of the through hole (10a) on the other surface (10S) side of the insulating substrate 10, inside of the opening part being filled with the sealing member 5. In the example of FIG. 4J, the second metal film 32 is formed on the entire surface on the other surface (10S) side of the insulating substrate 10. That is, the second metal film 32 is also formed on the first metal film 31 on the other surface (10S) of the insulating substrate 10 so as to be in contact with the first metal film 31. The shield layer 3 surrounding the electronic components (2a-2c) is formed by the first metal film 31 and the second metal film 32. After the second metal film 32 is formed on the entire surface on the other surface (10S) side of the insulating substrate 10, a portion that is functionally not particularly required may be removed by etching or the like. For example, a portion of the second metal film 32 that is neither above the through hole (10a) nor on the first metal film 31 may be removed. Further, when multiple electronic component built-in substrates 1 are manufactured from a large-sized insulating substrate 100 (see FIG. 4B), the second metal film 32 in vicinities of cutting lines (S) (see FIG. 4L) for singulation may be removed.

After the formation of the second metal film 32, the covering layer 33 covering the second metal film 32 is formed. For example, the covering layer 33 is formed from an electrolytic plating film of a material different from that of the second metal film 32 by electrolytic plating using the second metal film 32 as a seed layer. For the material of the covering layer 33 in this case, for example, nickel is used when the second metal film 32 is formed of copper. The material of the covering layer 33 that is formed from a plating film is not limited to nickel, and can be appropriately selected according to the material of the second metal film 32.

The covering layer 33 may also be formed using a resin material. For example, a resin formed in a film-like shape is laminated on the second metal film 32 and is heated. The resin material, once melted due to the heating, is in close contact with the second metal film 32. The resin material is fully cured by further heating. Thereby, the covering layer 33 is aimed. The covering layer 33 formed from a resin material is preferable in that the second metal film 32 can be insulated from an external conductor. An example of the material for the covering layer 33 in this case is an epoxy resin. A material having a linear expansion coefficient equal to that of the material of the sealing member 5 is preferable as the material for the covering layer 33. This is because a thermal stress generated in the second metal film 32 is likely to be small.

In the example of the manufacturing method of the embodiment illustrated in FIG. 4A to 4L, after the formation of the covering layer 33, the carrier metal foil 82 is separated from the metal foil 81, together with the base substrate 83. For example, a thermoplastic adhesive that bonds the metal foil 81 and the carrier metal foil 82 to each other is softened by heating, and, in this state, the metal foil 81 and the carrier metal foil 82 are pulled apart. In the case where the metal foil 81 and the carrier metal foil 82 are bonded to each other only at an outer peripheral portion, the bonding portion may be cut off.

The metal foil 81, that is, the base member 8, exposed by the separation from the carrier metal foil 82 is removed. For example, the metal foil 81 is removed by etching. During the etching, the second metal film 32 is covered by the covering layer 33. Therefore, even when the same material as the metal foil 81 is used for the second metal film 32, the second metal film 32 is not removed.

When the metal foil 81 is removed by etching, the etching can be continued even after the metal foil 81 has disappeared so that the conductor pads of the second conductor layer (7b) are reliably electrically isolated from each other. During this process, the surface of the second conductor layer (7b) exposed by the disappearance of the metal foil 81 is etched. As a result, the surface of the second conductor layer (7b) can be recessed from the surface of the first resin insulating layer (74a) (see FIG. 3).

As illustrated in FIG. 4K, the bumps 73 can be formed on the exposed surfaces of the third and fourth conductor pads (7b1, 7b2). The bumps 73 are formed, for example, by printing a solder paste or positioning solder balls, and applying solder reflow. A material and a formation method for the bumps 73 are not particularly limited.

When the insulating substrate 10 has a margin portion other than the portion that forms the electronic component built-in substrate 1, the margin portion is cut off. For example, at positions indicated by two-dot chain lines (D) in FIG. 4K, the insulating substrate 10 is cut with a router or the like along with the first and second metal films 31, 32 and the first-third conductor layers (7a-7c). As a result, the electronic component built-in substrate 1 in a final form illustrated in FIG. 1 is obtained. Further, when multiple electronic component built-in substrates 1 are simultaneously manufactured using a large-sized insulation substrate 100 (see FIG. 4B), individual electronic component built-in substrates 1 are singulated. For example, the large format insulating substrate 100 is cut at positions of cutting lines (S) around individual through holes (10a) indicated by two-dot chain line in FIG. 4L. As a result, the multiple electronic component built-in substrates 1 forming in an array are singulated into individual electronic component built-in substrates 1 each having a final outer shape. By the above processes, the electronic component built-in substrate 1 illustrated in FIG. 1 is completed.

In the example of the manufacturing method of the embodiment illustrated in FIG. 4A-4L, the carrier metal foil 82 is separated from the metal foil 81, that is, the base member 8, after the formation of the covering layer 33. However, when the second conductor pad (7a2) and the insulating substrate 10 can be connected to each other, the carrier metal foil 82 and the metal foil 81 can be separated from each other in any process after the formation of the solder resist layer 6. Further, in this case, the removal of the metal foil 81 may also be performed in any process after the separation of the carrier metal foil 82 and the metal foil 81. In that case, a protective film formed of a resin such as polyethylene terephthalate may be provided on an exposed surface of the metal foil 81 after the separation of the carrier metal foil 82 and on exposed surfaces of the second conductor layer (7b) and the first resin insulating layer (74a) after the removal of the metal foil 81.

In a high frequency module, electronic components such as an integrated circuit device and a transistor that form a transmission circuit may be mounted on a substrate. These electronic components may be covered in a case on each substrate. Therefore, a total thickness of the module may become a sum of a total thickness of the substrate and the electronic components, a wall thickness of the case, and an appropriate clearance length between the case and the electronic components.

An electronic component built-in substrate according to an embodiment of the present invention includes an insulating substrate that has a through hole that accommodates an electronic component, the electronic component that is accommodated in the through hole, and a sealing member that is filled in the through hole and covers the electronic component. A first metal film is formed on an inner wall that surrounds through hole of the insulating substrate. On one side of the insulating substrate, a terminal of the electronic component is exposed from the sealing member. On another side, an opposite side of the one side, of the insulating substrate, a second metal film is formed. An opening part of the through hole on the other side is covered by the second metal film.

A method for manufacturing an electronic component built-in substrate according to another embodiment of the present invention includes: forming a through hole in an insulating substrate; forming a first metal film on an inner wall that surround the through hole of the insulating substrate; preparing a base member that closes an opening part on one side of the through hole; superimposing the base member and the insulating substrate; positioning an electronic component on the base member in the through hole directly or via a conductor; filling a resin material in the through hole; forming a second metal film that covers an opening part of the through hole on an opposite side of the base member so as to be in contact with the first metal film; and removing the base member.

According to an embodiment of the present invention, the electronic component is accommodated in the through hole surrounded by the metal films. Therefore, a thin electronic component built-in substrate with reduced radio wave leakage to the outside can be provided. Further, an external electrical circuit and the terminal of the electronic component can be connected with a short path. Therefore, deterioration in quality of input and out signals is less likely to occur and characteristics of the electronic component built-in substrate can be stabilized. Further, a case or the like is not needed. Therefore, the electronic component built-in substrate can be easily manufactured at a low manufacturing cost.

Obviously, numerous modifications and variations of the present invention are possible in light of the above teachings. It is therefore to be understood that within the scope of the appended claims, the invention may be practiced otherwise than as specifically described herein.

1. An electronic component built-in substrate, comprising:
an insulating substrate having a through hole and an inner wall surrounding the through hole;
an electronic component accommodated in the through hole of the insulating substrate;
a sealing member filling the through hole such that the sealing member is covering the electronic component in the through hole of the insulating substrate and exposing a terminal of the electronic component on a first side of the insulating substrate; and
a shield layer structure comprising a first metal film and a second metal film formed such that the first metal film is formed on the inner wall of the insulating substrate and surrounding the through hole of the insulating substrate and that the second metal film is formed on a second side of the insulating substrate on an opposite side with respect to the first side and covering an opening of the through hole on the second side of the insulating substrate.

2. An electronic component built-in substrate according to claim 1, wherein the first metal film is extending to a surface of the insulating substrate on the second side of the insulating substrate and connecting to the second metal film such that the shield layer structure is enclosing the electronic component other than an opening of the through hole on the first side of the insulating substrate.

3. An electronic component built-in substrate according to claim 1, wherein the first metal film is extending to a surface of the insulating substrate on the first side of the insulating substrate such that the first metal film is surrounding an opening of the through hole on the first side of the insulating substrate.

4. An electronic component built-in substrate according to claim 1, further comprising:
a first conductor layer formed on the first side of the insulating substrate and comprising a plurality of first conductor pads; and
a solder resist layer formed on the first conductor layer such that the solder resist layer has a plurality of openings exposing the plurality of first conductor pads respectively,
wherein the plurality of first conductor pads is positioned to be connected to the terminal of the electrical component.

5. An electronic component built-in substrate according to claim 4, wherein the first meal film of the shield layer structure is extending to a surface of the insulating substrate on the first side of the insulating substrate, and the first conductor layer includes a plurality of second conductor pads positioned to be connected to the first metal film on the surface of the insulating substrate on the first side of the insulating substrate.

6. An electronic component built-in substrate according to claim 4, further comprising:
a first resin insulating layer formed on the first side of the insulating substrate such that the solder resist layer and the first conductor layer in positioned between the first resin insulating layer and the insulating substrate; and
a second conductor layer embedded in the first resin insulating layer such that the second conductor layer has an exposed surface recessed from a surface of the first resin insulating layer and comprises a plurality of third conductor pads and a plurality of fourth conductor pads,
wherein the second conductor layer is formed such that the plurality of third conductor pads electrically connects to the terminal of the electronic component and the plurality of fourth conductor pads electrically connects to the first metal film on the surface of the insulating substrate on the first side of the insulating substrate.

7. An electronic component built-in substrate according to claim 4, wherein the first conductor layer is formed such that each of the first conductor pads has an exposed surface recessed from a surface of the solder resist layer.

8. An electronic component built-in substrate according to claim 1, wherein the first metal film is extending to a surface of the insulating substrate on the first side of the insulating substrate such that the first metal film on the surface of the insulating substrate has a surface which forms coplanar with a surface of the terminal of the electronic component.

9. An electronic component built-in substrate according to claim 1, further comprising:
a second electronic component accommodated in the through hole of the insulating substrate,
wherein the sealing member is covering the electronic component and second electronic component in the through hole of the insulating substrate and exposing the terminal of the electronic component and a terminal of the second electronic component on the first side of the insulating substrate.

10. An electronic component built-in substrate according to claim 1, further comprising:
a second electronic component accommodated in the through hole of the insulating substrate,
wherein the sealing member is covering the electronic component and second electronic component in the through hole of the insulating substrate and exposing the terminal of the electronic component and a terminal of the second electronic component on the first side of the insulating substrate, the electronic component is a passive component, and the second electronic component is an active component.

11. An electronic component built-in substrate according to claim 1, further comprising:
a plurality of electronic components accommodated in the through hole of the insulating substrate,
wherein the sealing member is covering the electronic component and plurality of electronic components in the through hole of the insulating substrate and exposing the terminal of the electronic component and terminals of the electronic components on the first side of the insulating substrate, and the electronic component and plurality of electronic components include a passive component and an active component.

12. An electronic component built-in substrate according to claim 1, further comprising:
a plurality of electronic components accommodated in the through hole of the insulating substrate,
wherein the sealing member is covering the electronic component and plurality of electronic components in the through hole of the insulating substrate and exposing the terminal of the electronic component and terminals of the electronic components on the first side of the insulating substrate.

13. An electronic component built-in substrate according to claim 2, wherein the first metal film is extending to a surface of the insulating substrate on the first side of the insulating substrate such that the first metal film is surrounding an opening of the through hole on the first side of the insulating substrate.

14. An electronic component built-in substrate according to claim 2, further comprising:
a first conductor layer formed on the first side of the insulating substrate and comprising a plurality of first conductor pads; and
a solder resist layer formed on the first conductor layer such that the solder resist layer has a plurality of openings exposing the plurality of first conductor pads respectively,
wherein the plurality of first conductor pads is positioned to be connected to the terminal of the electrical component.

15. An electronic component built-in substrate according to claim 14, wherein the first meal film of the shield layer structure is extending to a surface of the insulating substrate on the first side of the insulating substrate, and the first conductor layer includes a plurality of second conductor pads positioned to be connected to the first metal film on the surface of the insulating substrate on the first side of the insulating substrate.

16. An electronic component built-in substrate according to claim 14, further comprising:
a first resin insulating layer foiled on the first side of the insulating substrate such that the solder resist layer and the first conductor layer in positioned between the first resin insulating layer and the insulating substrate; and
a second conductor layer embedded in the first resin insulating layer such that the second conductor layer has an exposed surface recessed from a surface of the first resin insulating layer and comprises a plurality of third conductor pads and a plurality of fourth conductor pads,
wherein the second conductor layer is formed such that the plurality of third conductor pads electrically connects to the terminal of the electronic component and the plurality of fourth conductor pads electrically connects to the first metal film on the surface of the insulating substrate on the first side of the insulating substrate.

17. A method for manufacturing an electronic component built-in substrate, comprising:
forming an insulating substrate having a through hole and an inner wall surrounding the through hole;
forming a first metal film on the inner wall of the insulating substrate;
positioning a base member on a first side of the insulating substrate such that an opening of the through hole on the first side is closed by the base member;
positioning an electronic component on the base member in the through hole directly or via a conductor;
filling a resin material in the through hole such that the resin material foil is a sealing member filling the through hole and covering the electronic component in the through hole of the insulating substrate;
forming a second metal film on a second side of the insulating substrate on an opposite side with respect to the first side such that the second metal film covers an opening of the through hole on the second side and makes contact with the first metal film; and
removing the base member from the insulating substrate such that the sealing member exposes a terminal of the electronic component on the first side of the insulating substrate,
wherein the first metal film and the second metal film form a shield layer structure.

18. A method for manufacturing an electronic component built-in substrate according to claim 17, further comprising:
preparing the base member,
wherein the preparing of the base member comprises forming a conductor layer having a conductor pattern on a metal foil or a resin insulating layer formed on the metal foil, and forming a solder resist layer on the conductor layer such that the solder resist layer has an opening, the positioning of the base member comprises soldering the insulating substrate to the conductor layer of the base member, and the positioning of the electronic component comprises soldering the electronic component to the conductor layer of the base member.

19. A method for manufacturing an electronic component built-in substrate according to claim 18, wherein the insulating substrate and the electronic component are soldered to the conductor layer of the base member by solder reflow in a same process.

20. A method for manufacturing an electronic component built-in substrate according to claim 17, further comprising:
polishing a surface of the sealing member prior to the forming of the second metal film such that the surface of the sealing member forms coplanar with a contact surface of the first metal film on which the second metal film makes contact with the first metal film.
